(19) United States
(12) Patent Application Publication
(10) Pub. No.: US 2015/0280164 A1
(43) Pub. Date: Oct. 1, 2015

(54) ORGANIC LIGHT-EMITTING DIODE HAVING AN INVERSE ENERGY LEVEL LAYER

(71) Applicant: CHUNGHWA PICTURE TUBES, LTD., Taoyuan (TW)

(72) Inventors: Chih-Hao LIN, Taoyuan County (TW); Yi-Chun SUN, Taoyuan County (TW)

(21) Appl. No.: 14/297,640

(22) Filed: Jun. 6, 2014

(30) Foreign Application Priority Data
Mar. 26, 2014 (TW) 103111286

(51) Int. Cl. H01L 51/50; H01L 51/00; H01L 51/56

(52) U.S. Cl. CPC H01L 51/5044; H01L 51/56; H01L 51/5016; H01L 51/0003; H01L 51/5004; H01L 2251/558

(57) ABSTRACT

An organic light-emitting diode (OLED) includes a first electrode, a hole injection layer formed on the first electrode, an inverse energy level layer formed on the hole injection layer, a hole transport layer formed on the inverse energy level layer, a light-emitting layer formed on the hole transport layer, an electron transport layer formed on the light-emitting layer, an electron injection layer formed on the electron transport layer, and a second electrode formed on the electron injection layer. The work function of the inverse energy level layer is higher than the highest occupied molecular orbital (HOMO) of the hole injection layer and the hole transport layer.

### RELATED APPLICATIONS

This application claims priority to Taiwanese Application Serial Number 103111286, filed Mar. 26, 2014, which is herein incorporated by reference.

### BACKGROUND

1. Field of Invention

The present invention relates to a light-emitting diode. More particularly, the present invention relates to an organic light-emitting diode (OLED).

2. Description of Related Art

As the progress in technology, electronic display are required to be thinner, lightweight and compact, power saving, and high-definition. However, a general liquid crystal display (LCD) has limitations on like viewing angle and speed of response, and needs a backlight source in displaying. An organic light-emitting diode (LED) features self-luminescence, flexibility, wild viewing angle, high speed of response, simple manufacturing process, thinness, lightness, low power consumption, etc., and is regarded as the ultimate display technology and one of the candidates of next-generation lighting. In particular, for white OLED the white light generated by the white OLED has its preference in the applications of lighting and display.

The basic electroluminescent structure of an OLED includes organic light-emitting molecules sandwiched by two electrodes. When a voltage is applied to the OLED, holes and electrons are injected to a light-emitting layer by an anode and a cathode, respectively. Those holes and electrons then combine in the light-emitting layer, which is made of light-emitting molecules, to excite the light-emitting molecules to an excited state from a ground state. When the light-emitting molecules come back to the ground state from the excited state, energy is released in a form of light; that is, electric energy is transformed into light wave. In short, electric currents flow through the light-emitting layer to enable the light-emitting molecules in the light-emitting layer to emit light.

However, the hole-electron pairing in the light-emitting layer of the conventional OLED structure is poor, which leads to the deviation from the desired emitted light. Concerning the structure of the conventional white OLED, the emitted light at first is not pure white, and thus the application of the white OLED is limited. Accordingly, how to make the light emitted by the OLED as close to a pure colored light as possible becomes an important issue.

### SUMMARY

An objective of the present invention is to provide an organic light-emitting diode (OLED) having adjusted structure to make the electroluminescent light emitted by the OLED closer to pure colored light.

An aspect of the present invention is to provide an OLED, including a first electrode, a hole injection layer formed on the first electrode, an inverse energy level layer formed on the hole injection layer, a hole transport layer formed on the inverse energy level layer, a light-emitting layer formed on the hole transport layer, an electron transport layer formed on the light-emitting layer, an electron injection layer formed on the electron transport layer, and a second electrode formed on the electron injection layer. The work function of the inverse energy level layer is higher than the highest occupied molecular orbital (HOMO) of the hole injection layer and the hole transport layer.

According to one embodiment of the present invention, the material of the inverse energy level layer includes lithium fluoride (LiF).

According to one embodiment of the present invention, the inverse energy level layer has a thickness equal or smaller than 5 angstroms (Å).

According to one embodiment of the present invention, the OLED includes a white organic light-emitting diode.

According to one embodiment of the present invention, the light-emitting layer includes a first light-emitting layer and a second light-emitting layer, wherein the first light-emitting layer includes a red light-emitting material and a green light-emitting material, and the second light-emitting layer includes a blue light-emitting material.

According to one embodiment of the present invention, the material of the light-emitting layer includes a phosphorescence light-emitting material, a fluorescence light-emitting material, or combination thereof.

According to one embodiment of the present invention, the composition of the material of the light-emitting layer includes one of the phosphorescence light-emitting material and the fluorescence light-emitting material.

According to one embodiment of the present invention, the light-emitting layer comprises a first light-emitting layer and a second light-emitting layer, and the composition of the material of the light-emitting layer includes the phosphorescence light-emitting material and the fluorescence light-emitting material. In this embodiment, the OLED further includes a barrier layer between the first light-emitting layer and the second light-emitting layer.

According to one embodiment of the present invention, the method for forming the OLED comprises thermal evaporation.

Advantage of the present invention is that there is an additional inverse energy level layer between the hole injection layer and the hole transport layer. By the way of inverse energy level, the hole-electron pairing in the light-emitting layer can be improved. Accordingly, the electroluminescent light emitted by the OLED can be closer to the pure colored light.

### BRIEF DESCRIPTION OF THE DRAWINGS

The invention can be more fully understood by reading the following detailed description of the embodiment, with reference made to the accompanying drawings as follows.

FIG. 1 is a cross-sectional view of an OLED according to one embodiment of the present invention;

FIG. 2 is a cross-sectional view of an OLED according to another embodiment of the present invention;

FIG. 3 is a diagram of CIE chromaticity coordinate values of embodiments of the present invention and a comparative example; and

FIG. 4 is a CIE 1931 color space chromaticity diagram of embodiments of the present invention and a comparative example.

### DETAILED DESCRIPTION

The structure of a conventional OLED includes a first electrode, a hole injection layer formed on the first electrode, a hole transport layer formed on the hole injection layer, a light-emitting layer formed on the hole transport layer, an electron transport layer formed on the light-emitting layer, an electron injection layer formed on the electron transport layer, and a second electrode formed on the electron injection layer. The efficacy of electroluminescence of the OLED is related to the hole-electron pairing in the light-emitting layer. Under the influence of the electric field, the mobility of the holes in the anode is better than the electrons generated by the cathode, and thus the quantity of holes capable of being transmitted to the light-emitting layer is more than that of electrons. Therefore, the hole-electron pairing in the light-emitting layer of the conventional OLED is poor, and results in that the electroluminescent light emitted by the conventional OLED tends to be biased, that is, the emitted light source is not pure colored light.

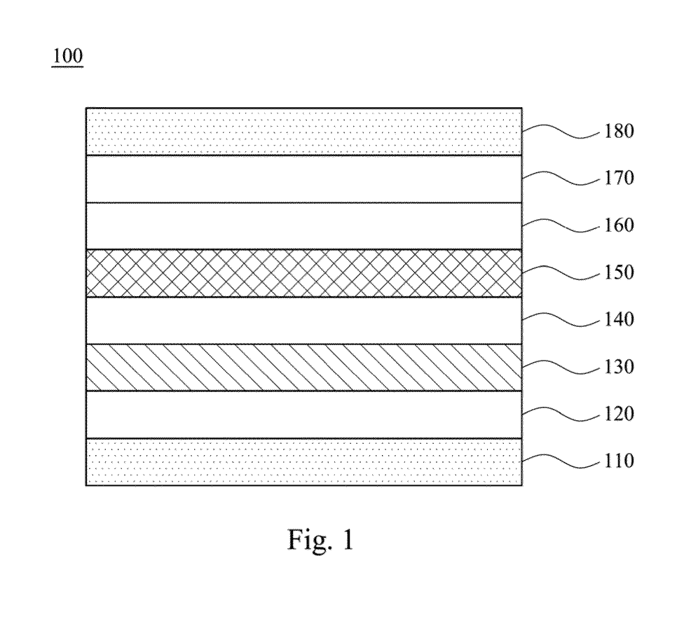

FIG. 1 is a cross-sectional view of an OLED 100 according to one embodiment of the present invention. The OLED 100 includes a first electrode 110, a hole injection layer 120 formed on the first electrode 110, an inverse energy level layer 130 formed on the hole injection layer 120, a hole transport layer 140 formed on the inverse energy level layer 130, a light-emitting layer 150 formed on the hole transport layer 140, an electron transport layer 160 formed on the light-emitting layer 150, an electron injection layer 170 formed on the electron transport layer 160, and a second electrode 180 formed on the electron injection layer 170. The work function of the inverse energy level layer 130 is higher than the highest occupied molecular orbital (HOMO) of the hole injection layer 120 and the hole transport layer 140. The work function is the minimum energy required to remove an electron immediately from the interior of a solid to the solid surface, and the unit is usually electron volt (eV). The HOMO is the highest-energy orbital of the molecular orbital occupied by electrons.

In order to adjust the quantities of holes (not shown) and electrons (not shown), the present invention adds the inverse energy level layer 130 between the hole injection layer 120 and the hole transport layer 140. Because the work function of the inverse energy level layer 130 is higher than the HOMO of the hole injection layer 120 and the hole transport layer 140, the band gap between the inverse energy level layer 130 and the hole transport layer 140 is larger than the band gap between the hole injection layer and the hole transport layer of the conventional OLED. By the way of inverse energy level, the energy barrier for holes hopping to the hole transport layer 140 is elevated, and more energy is required for holes to enter the hole transport layer 140. Therefore, the quantity of holes in the light-emitting layer 150 may be reduced, and the hole-electron pairing in the light-emitting layer 150 may be improved. Accordingly, the CIE chromaticity coordinate of the electroluminescent light emitted by the OLED 100 may be controlled and closer to the pure colored light.

The OLED of the present invention may include a plurality of hole transport layers in consideration of energy level.

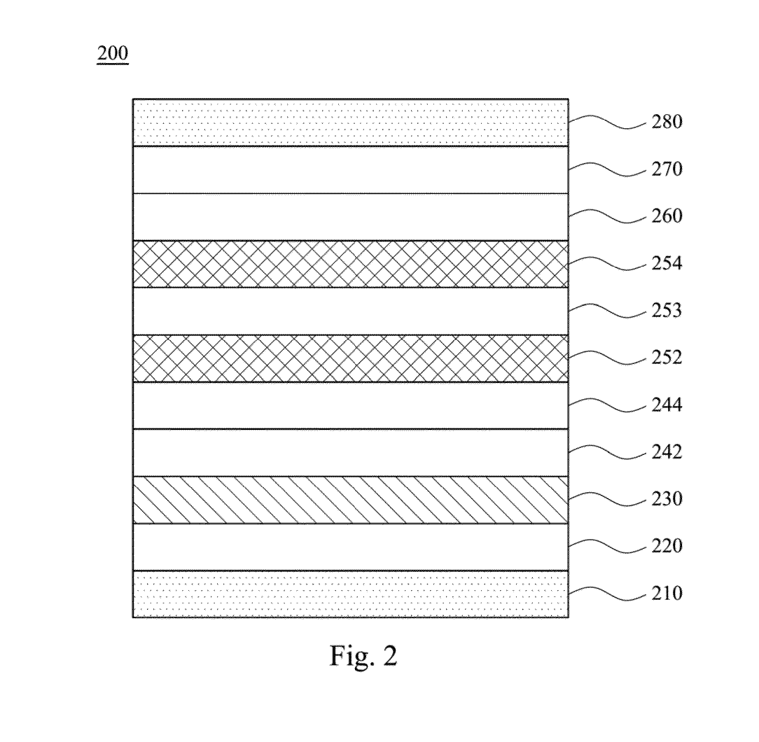

FIG. 2 is a cross-sectional view of an OLED 200 according to another embodiment of the present invention. The OLED 200 is a white OLED, including a first electrode 210, a hole injection layer 220 formed on the first electrode 210, an inverse energy level layer 230 formed on the hole injection layer 220, a first hole transport layer 242 formed on the inverse energy level layer 230, a second hole transport layer 244 formed on the first hole transport layer 242, a first light-emitting layer 252 formed on the second hole transport layer 244, a barrier layer 253 formed on the first light-emitting layer 252, second light-emitting layer 254 formed on the barrier layer 253, an electron transport layer 260 formed on the second light-emitting layer 254, an electron injection layer 270 formed on the electron transport layer 260, and a second electrode 280 formed on the electron injection layer 270. The work function of the inverse energy level layer 230 is higher than the HOMO of the hole injection layer 220, the first hole transport layer 242, and the second hole transport layer 244. In this embodiment, because the materials of the first light-emitting layer 252 and the second light-emitting layer 254 include both phosphorescence light-emitting material and fluorescence light-emitting material, in consideration of the arrangement between light-emitting materials of two light-emitting layers 252 and 254, there is the barrier layer 253 between the first light-emitting layer 252 and the second light-emitting layer 254 as a barrier to blur the interface between light-emitting materials having different properties.

The following are several embodiments to discuss the effect of the thickness of the inverse energy level layer on CIE chromaticity coordinate, wherein the basic stack structure of the embodiments is generally the same as the stack structure of the OLED 200, and the material of the inverse energy level layer is lithium fluoride (LiF).

In Embodiment 1, the hole injection layer has a thickness of 300 angstroms (Å); the inverse energy level layer (LiF layer) has a thickness of 3 Å; the first hole transport layer has a thickness of 300 Å; the second hole transport layer has a thickness of 200 Å; the first light-emitting layer has a thickness of 25 Å, and includes a red light-emitting material and a green light-emitting material; the barrier layer has a thickness of 5 Å; the second light-emitting layer has a thickness of 300 Å, and includes a blue light-emitting material; the electron transport layer has a thickness of 300 Å; the electron injection layer has a thickness of 10 Å; and the second electrode, which is a cathode, has a thickness of 1600 Å.

In this embodiment, the HOMO of the hole injection layer, the first hole transport layer, and the second hole transport layer are about 5.0-6.0 electron volt (eV). The lowest unoccupied molecular orbital (LUMO) of the light-emitting layers are about 2/−3.0 eV, and the LUMO of the electron transport layer is about 4.0 eV.

An indium tin oxide (ITO) transparent electrode is used as the material of the first electrode in this embodiment. In addition, the red light-emitting material and the green light-emitting material are phosphorescence light-emitting material, and the blue light-emitting material is fluorescence light-emitting material in this embodiment, and thus there is the barrier layer between the first light-emitting layer and the second light-emitting layer to blur the interface between light-emitting materials having different properties.

The structure of Embodiment 2 is generally the same as Embodiment 1, while the thickness of the LiF layer in Embodiment 2 is 5 Å.

Comparative Example 1 is a conventional OLED, which has no LiF layer between the hole injection layer and the hole transport layer. Structures of other layers in Comparative Example 1 are generally the same as Embodiment 1.

Table 1 shows the conditions and results of Embodiment 1, Embodiment 2, and Comparative Example 1.

TABLE 1

| | Thickness | Current | Voltage | CIE chromaticity | CCT |
|---|---|---|---|---|---|
| Sample | of LiF (Å) | (mA) | (V) | coordinate (x, y) | (K) |
| Comparative | 0 | 90 | 6.46 | (0.417, 0.461) | 3750 |
| Example 1 | | | | | |
| Embodiment 1 | 3 | 90 | 6.75 | (0.404, 0.420) | 3742 |
| Embodiment 2 | 5 | 90 | 6.03 | (0.369, 0.395) | 4292 |

CIE 1931 color space was created by the International Commission on Illumination (CIE) in 1931, which refers to a mathematically defined color space. The main graph of the CIE 1931 color space is CIE 1931 color space chromaticity diagram, and CIE chromaticity coordinate is the x and y coordinate value on the CIE 1931 color space chromaticity diagram. Correlated color temperature (CCT) represents that when the color of the light emitted by a light source resembles the color of the black body radiator under a specific temperature, the specific temperature of the black body radiator is the CCT of the light source. The unit of the CCT is absolute temperature (Kelvin, K).

As the results shown in Table 1, comparing to Comparative Example 1 having no LiF layer, Embodiment 1 and Embodiment 2 having the thin layer of LiF material inserted between the hole injection layer and the hole transport layer have decreased values of CIE chromaticity coordinate by the way of inverse energy level. Thus, the electroluminescent light emitted by the OLED of the present embodiments can be closer to the CIE chromaticity coordinate of white light (0.33,0.33). Moreover, the addition of the LiF layer may also control the CCT of the electroluminescent light emitted by the OLED. The color temperature of white light is about 3000-3800 K, and light having a color temperature over 3800 K is bluish white. The CCT of Embodiment 1 is close to 3800 K, and the CCT of Embodiment 2 is slightly above 3800 K. These results represent that the white OLED of the present embodiments have a better effect upon bluish white.

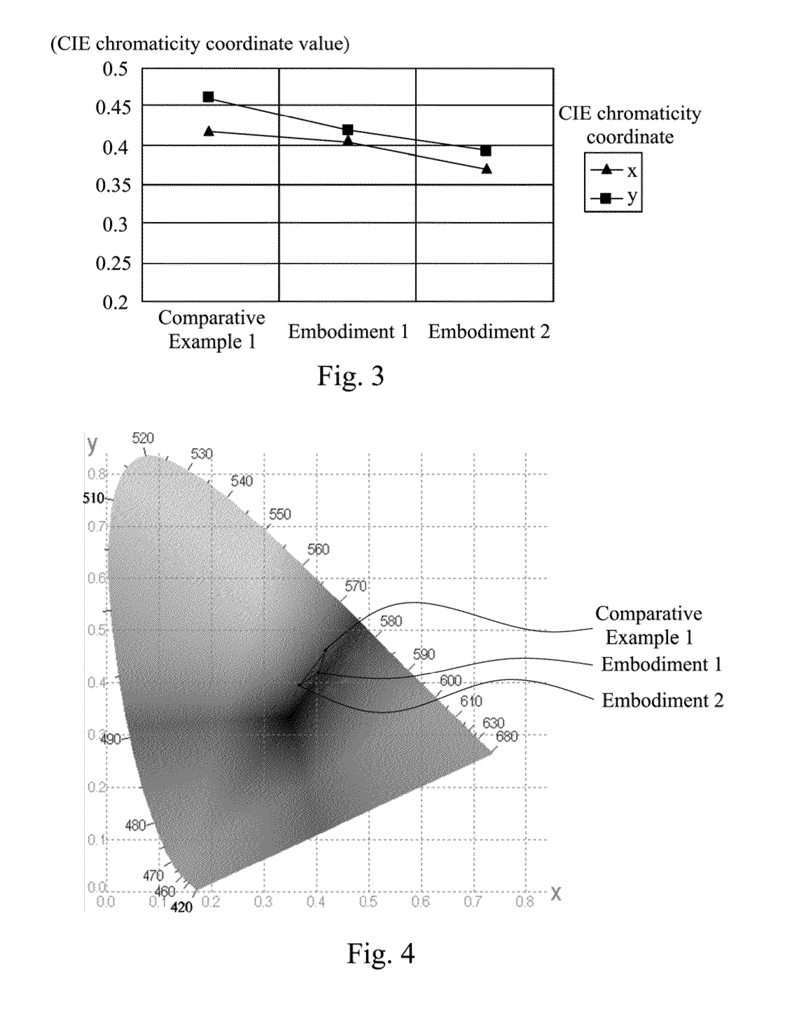

Referring to FIG. 3, which is a diagram of the CIE chromaticity coordinate values of Embodiment 1 and Embodiment 2 of the present invention and Comparative Example 1. As shown in FIG. 3, the x and y value of the CIE chromaticity coordinate decrease as the thickness of LiF layer increases. Comparing to Comparative Example 1, the CIE chromaticity coordinate (x,y) of Embodiment 1 and Embodiment 2 are closer to the CIE chromaticity coordinate of white light (0.33,0.33).

Referring to FIG. 4, which is a CIE 1931 color space chromaticity diagram of Embodiment 1 and Embodiment 2 of the present invention and Comparative Example 1. As shown in FIG. 4, comparing to Comparative Example 1, the locations of Embodiment 1 and Embodiment 2 on the CIE 1931 color space chromaticity diagram are closer to the white area of the CIE 1931 color space chromaticity diagram.

The organic light-emitting diode of the present invention adjusts the structure by adding the inverse energy level layer between the hole injection layer and the hole transport layer. By the way of inverse energy level, the hole-electron pairing in the light-emitting layer is improved, and thus the chromaticity coordinate (CIE 1931) may be controlled to be closer to pure colored light area. Thereby, the desired color and color temperature of the light emitted by OLED may be easily controlled.

It will be apparent to those ordinarily skilled in the art that various modifications and variations can be made to the structure of the present invention without departing from the scope or spirit of the invention. In view of the foregoing, it is intended that the present invention cover modifications and variations of this invention provided they fall within the scope of the following claims.

1. An organic light-emitting diode, comprising:
a first electrode;
a hole injection layer formed on the first electrode;
an inverse energy level layer formed directly on the hole injection layer;
a hole transport layer formed directly on the inverse energy level layer;
a light-emitting layer formed on the hole transport layer;
an electron transport layer formed on the light-emitting layer;
an electron injection layer formed on the electron transport layer; and
a second electrode formed on the electron injection layer,
wherein work function of the inverse energy level layer is higher than highest occupied molecular orbital (HOMO) of the hole injection layer and the hole transport layer.

2. The organic light-emitting diode of claim 1, wherein the material of the inverse energy level layer comprises lithium fluoride (LiF).

3. The organic light-emitting diode of claim 2, wherein the inverse energy level layer has a thickness equal or smaller than 5 angstroms (Å).

4. The organic light-emitting diode of claim 1, wherein the organic light-emitting diode comprises a white organic light-emitting diode.

5. The organic light-emitting diode of claim 4, wherein the light-emitting layer comprises a first light-emitting layer and a second light-emitting layer, wherein the first light-emitting layer comprises a red light-emitting material and a green light-emitting material, and the second light-emitting layer comprises a blue light-emitting material.

6. The organic light-emitting diode of claim 1, wherein the material of the light-emitting layer comprises a phosphorescence light-emitting material, a fluorescence light-emitting material, or combination thereof.

7. The organic light-emitting diode of claim 6, wherein the composition of the material of the light-emitting layer comprises one of the phosphorescence light-emitting material and the fluorescence light-emitting material.

8. The organic light-emitting diode of claim 6, wherein the light-emitting layer comprises a first light-emitting layer and a second light-emitting layer, and the composition of the material of the light-emitting layer comprises the phosphorescence light-emitting material and the fluorescence light-emitting material.

9. The organic light-emitting diode of claim 8, further comprising a barrier layer between the first light-emitting layer and the second light-emitting layer.

10. The organic light-emitting diode of claim 1, wherein the organic light-emitting diode is made through a process comprising thermal evaporation.
